(19) United States
(12) Patent Application Publication
(10) Pub. No.: US 2001/0053410 A1
(43) Pub. Date: Dec. 20, 2001

(54) Process for repairing a coated component

(76) Inventors: John Fernihough, Ennetbaden (CH); Abdus S. Khan, Ennetbaden (CH); Maxim Konter, Klingnau (CH); Markus Oehl, Waldshut-Tiengen (DE); Hans-Joachim Dorn, Ennetbaden (CH)

Correspondence Address: BURNS DOANE SWECKER & MATHIS L L P, POST OFFICE BOX 1404, ALEXANDRIA, VA, 22313-1404, US

(21) Appl. No.: 09/870,502

(22) Filed: Jun. 1, 2001

(30) Foreign Application Priority Data
Jun. 5, 2000 (EP) 00112068.2

(51) Int. Cl. C23C 16/00; B05D 3/00; B05D 1/32

(52) U.S. Cl. 427/142; 427/250; 427/328; 427/282

(57) ABSTRACT

The invention relates to a process of repairing a MCrAlY-coating of an article, which has being exposed to the hot gases of, for example, a gas turbine. The MCrAlY-coating is examined and repaired only locally where it is needed and then, subsequently, on top of the MCrAlY-coating the article is aluminized and/or chromized, avoiding the stripping of the whole coating and re-coating over the entire surface of the article. This is for replenishing the coating of Al and/or Cr that become depleted during engine operation, in an easy, cost and time saving manner.

### FIELD OF INVENTION

The invention relates to a process of repairing a coated component according to the preamble of claim 1.

### STATE OF THE ART

Most turbine components are coated for protection from oxidation and/or corrosion with, for example, a MCrAlY coating (base coat) and some are also coated with a thermal barrier coating (TBC) for thermal insulation. The demands of operation of the parts in a gas turbine often lead to the degradation of the coating before the structural integrity of the underlying part itself is degraded. Hence, the base coat and TBC must be removed and reapplied. Such processes are known from EP-A2-813 930, EP-A1-298 309 or U.S. Pat. No. 5,728,227.

The coatings must be replaced because during service they degrade by forming protective aluminium and/or chromium oxides on the surface, which periodically spall off and must be replaced by fresh Al and/or Cr from the coating. Hence, Al and/or Cr diffuses from the interior of the coating towards the coating surface to continually replenish the protective oxides. It is known that the level of degradation of a coating (i.e. the remaining life) can be characterised by the amount of Al and/or Cr, left in the coating compared with the amount first present in the originally applied coating.

It is also known that turbine blades and other components have only local areas of extremely high surface temperature during operation, whereas the rest of the component surface has a moderate temperature. This means that the environmentally protective coatings are degraded by far the most in these local areas of high temperature, which constitute about 5 to 20% of the total surface area of the whole component, and only moderately over the rest of the surface area. For older gas turbine engines where components operate at a low temperature, it is widely practised to locally replace the depleted coatings (MCrAlY) in the local hot areas, but leave the rest of the coating alone since it is not yet depleted in Al and/or Cr to the point that it cannot survive another inspection interval of the engine operation.

However, modern gas turbines operate at higher temperatures, where local hot spots on the blades completely deplete Al from the MCrAlY coatings, and partial depletion of Al from the coating over the rest of the blade is such that they usually can not survive another inspection interval. Therefore the entire coating must be stripped and replaced. The stripping of the coating involves a treatment with very aggressive acid which also removes some of the base material of the blade, may lead to weakening of the material at the surface, is expensive and time consuming. Re-coating of the blade is also expensive, and both operations have a certain scrap rate due to problems in the process.

### SUMMARY OF THE INVENTION

It is object of the present invention to find a method of restoring enough Al and/or Cr to the partially depleted MCrAlY-coating on the cooler parts of the turbine blades so that it could survive a complete inspection interval of engine operation, while only locally repairing the “hot spots” which are completely depleted and beyond such restoration due to the excessive coating spallation.

According to the invention a process was found of repairing an article with a MCrAlY-coating according to the preamble of the claim 1 characterised in that the MCrAlY-coating is repaired locally and the article is aluminised and/or chromised on the surface of the article on top of the MCrAlY-coating.

This method saves both time and investments costs because stripping and recoating using usual plasma spraying would be unnecessary. On the other hand is it possible to replenish the amount of Al and Cr in the depleted surface of the article in an easy way.

The areas requiring local repair of the MCrAlY coating are by definition subject to the highest levels of depletion of Al and/or Cr. Associated with this depletion will be a significant thickness of depleted (non-functioning) MCrAlY coating and also of oxide scale. If the repair MCrAlY coating material is to properly bond to the substrate, all of the oxide scale must be removed, as much of the depleted coating as possible, without affecting the base material under the coating unless this also has been oxidized. Therefore, it is highly advantageous to prepare the areas requiring local MCrAlY repair by cleaning using any conventional means such as local chemical etching, grit blasting, grinding or other abrasive methods. This will ensure a long lasting bond of the newly applied coating material to the substrate.

Another advantage comes from the fact that the method is also applicable even when a ceramic coating is existent. The ceramic coating, which is on top of the MCrAlY-coating, can be removed with any possible means before applying the steps of the method of the invention and the article is re-coated with a ceramic coating thereafter.

In another embodiment the aluminising and/or chromising takes place before the locally repair of MCrAlY which is still possible to fulfil the same desired effect.

A further advantage would be that the problem of plugging the cooling holes with sprayed coating would be avoided. Since cooling holes offer local protection from high temperatures, the coating would not require local replacement close to the cooling holes. Thus, the coating could be locally replaced in the hot areas and then the entire blade aluminised without plugging the cooling holes with sprayed coatings. In any case it is possible to mask the cooling holes during the local coating repair or aluminising method according to the invention to avoid a reduction of the size cooling holes during the proposed method.

Of course, an article comprising an inner and an outer surface with a MCrAlY-coating will be aluminised and/or chromised at the said inner and at the said outer surface.

The enrichment with Al and/or Cr within the MCrAlY-coating is optimised when the aluminising and/or chromising is followed by a diffusion heat treatment. Alternatively a “high activity” aluminising can be used so that Al is deposited not only at a surface layer of the MCrAlY-coating, but diffuses into the MCrAlY-coating. Preferably the aluminising takes place with a gas phase method.

In another advantageous embodiment the local repair of the MCrAlY-coating takes place with a corrosion resistant coating containing a high amount of Cr. With that embodiment the corrosions resistance is enhanced at those areas most vulnerable thereby increasing the overall life time of article.

An article as it is claimed can possibly be a blade or a vane or any other part of a gas turbine engine coated with a MCrAlY-coating and exposed to a high temperature environment.

### DETAILED DESCRIPTION OF INVENTION

The invention is related to a process of repairing an article with a MCrAlY-coating being exposed to a high temperature environment. The article could possibly be a blade or a vane or any other part of a gas turbine engine such as a part of a burner chamber exposed to the hot gases of the gas turbine, the article being coated with a MCrAlY-coating to protect it against oxidation. The MCrAlY-coating derives its protective capabilities as a result of the formation of a thin uniform layer of alumina on the surface of the coating. The alumina film forms as a result of the oxidation of aluminium in the coating. With the continued exposure to oxidising conditions at elevated temperatures the alumina layer continues to grow in thickness and eventually spalls off. The spallation is accentuated by thermal cycling. The alumina layer reforms after spallation provided that sufficient aluminum remains deeper down in the coating. This results in an Al and/or Cr depleted coating with no more oxidation resistance.

The method of the invention consists of the steps of repairing the MCrAlY-coating of the article during inspection locally where it is needed and subsequently aluminising and/or chromising the article on the surface of the article on top of the MCrAlY-coating. For determination where the MCrAlY-coating has to be repaired locally any inspection method can be used.

The areas requiring local repair of the MCrAlY coating are by definition subject to the highest levels of depletion of Al and/or Cr. Associated with this depletion will be a significant thickness of depleted (non-functioning) MCrAlY coating and also of oxide scale. If the repair MCrAlY coating material is to properly bond to the substrate, all of the oxide scale must be removed, as as much of the depleted coating as possible, without affecting the base material under the coating unless this also has been oxidized. Therefore, it is highly advantageous to prepare the areas requiring local MCrAlY repair by cleaning using any conventional means such as local chemical etching, grit blasting, grinding or other abrasive methods. This will ensure a long lasting bond of the newly applied coating material to the substrate.

The method according to the present invention saves both time and investments costs because stripping and re-coating using conventional plasma spraying is unnecessary. On the other hand is it possible to replenish the amount of Al and Cr in the depleted surface of the article in an easy way, providing at the same time a possible way of prolonging the life time of the article.

MCrAlY protective overlay coatings are widely known in the prior art. They are a family of high temperature coatings, wherein M is selected from one or a combination of iron, nickel and cobalt. As an example U.S. Pat. No. 3,528,861 or U.S. Pat. No. 4,585,418 are disclosing such kind of oxidation resistant coatings. U.S. Pat. No. 4,152,223 as well discloses such method of coating and the coating itself.

The method of aluminising and chromising is described in e.g. Metals Handbook, Desk Edition (2. Edition), p.1166-1170, issued by the American Society of Metals (ASM). Possible ways of deposition is known in the state of the art as chemical or physical vapour deposition (CVD, PVD). Preferable the aluminising takes place with a gas phase method.

An advantage is that the problem of plugging the cooling holes with sprayed coating is avoided. Since cooling holes offer local protection from high temperatures, the coating would not require local replacement close to the cooling holes. Thus, the coating could be locally replaced in the hot areas and then the entire blade aluminised and/or chromised without plugging the cooling holes with sprayed coatings. In any case, it is possible to mask the cooling holes during the method according to the invention to avoid a reduction of the size cooling holes during application.

In an advantageous embodiment, the local repair of the MCrAlY-coating takes place with a corrosion resistant coating containing high amount of Cr. This could as an example be an alloy known as Ni—25Cr—5Al—Si—Ta—Y—coating, or just pure Cr. With that embodiment the oxidation resistance of the coating is maintained at the same time the corrosion resistant is achieved at areas highly needed due to the “hot spot” location, i.e. at points where it is exactly required. Thereby again increasing the overall life time of the article. The enrichment with Al and/or Cr within the MCrAlY-coating is even better accomplished when the aluminising and/or chromising is supported by a diffusion heat treatment. A heat treatment which can achieve the intended result is e.g. 2-4 hours in a vacuum furnace or in an inert or reducing gas atmosphere a temperature of 1080 degree C. or 1140 degree C. This effect is also or in addition possible by using an “high activity” aluminising so that it takes place not only at a superficial layer of nearly pure Al and/or Cr on the outer surface of the MCrAlY-coating, which would quickly melt or oxidise away during service, but the Al diffuses into MCrAlY-coating.

The method is also applicable even when a ceramic coating is existent. The ceramic coating (thermal barrier coating known as TBC), which is on top of the MCrAlY-coating, can removed with any possible means (e.g. acid cleaning) before applying the steps of the method of the invention and the article is re-coated with a TBC thereafter.

In another embodiment the aluminising and/or chromising takes place before the local repair of MCrAlY which is still possible to fulfil the same desired effect of replenishing the depleted coating.

Of course, when the article comprises an outer and an inner surface such as an internal cooling system, the MCrAlY-coating of the article will repaired on the outside and aluminising and/or chromising may be done on the inner surface as well as the outer surface.

1. Process of repairing a MCrAlY-coating of an article after use of this article in a high temperature environment, characterised in that
a. the MCrAlY-coating is repaired locally and
b. the article is aluminised and/or chromised so that Al or Cr is diffused into the MCrAlY-coating on the surface of the article.

2. Process of claim 1, characterised in that
the areas requiring local repair of the MCrAlY are prepared for the repair by cleaning using any conventional means such as local chemical etching, grit blasting, grinding or other abrasive methods.

3. Process of claim 1, characterised in that
a ceramic coating, which is on top of the MCrAlY-coating, is removed before applying the steps of the method of claim 1 and the article is recoated with a ceramic coating thereafter.

4. Process of claim 1, characterised in that
the article has an inner and an outer surface and it is aluminised and/or chromised at the inner and at the outer surface.

5. Process of any previous claims, characterised in that
the cooling holes are masked during the method according to the steps of claim 1.

6. Process of claim 1, characterised in that
the aluminising and/or chromising takes place before the local repair of the MCrAlY.

7. Process of claim 1, characterised in that
after the aluminising and/or chromising there is a diffusion heat treatment.

8. Process of claim 1, characterised in that
the local repair of the MCrAlY-coating takes place with a corrosion resistant coating containing a high amount of Cr.

9. Process of claim 1 where the article is at least aluminised, characterised in that
the article is aluminised so that Al does not concentrate only on the surface of the coating but diffuses over a broad depth in the coating.

10. Process of claim 1 where the article is in any case aluminised, characterised in that
the aluminising takes place with a gas phase method.

11. Process of claim 1, characterised in that
the article is a blade or a vane or any other part of a gas turbine engine exposed to a high temperature environment coated with a MCrAlY-coating.
